(19) United States
(12) Patent Application Publication
(10) Pub. No.: US 2008/0123786 A1
(43) Pub. Date: May 29, 2008

(54) METHOD AND APPARATUS FOR DETECTING AND CORRECTING MODULATED SIGNAL IMPAIRMENTS

(76) Inventors: Supat Wongwirawat, Langhorne, PA (US); Mark Hryszko, Doylestown, PA (US); Devan Namboodiri, Holland, PA (US); Raul A. Casas, Doylestown, PA (US)

Correspondence Address: MINTZ, LEVIN, COHN, FERRIS, GLOVSKY;AND POPEO, P.C., ONE FINANCIAL CENTER, BOSTON, MA, 02111, US

(21) Appl. No.: 11/947,105

(22) Filed: Nov. 29, 2007

Related U.S. Application Data
(60) Provisional application No. 60/867,687, filed on Nov. 29, 2006.
(60) Provisional application No. 60/884,874, filed on Jan. 13, 2007.

(51) Int. Cl. H03D 1/06; H04B 1/10; H04L 1/00; H04L 25/08

(52) U.S. Cl. 375/346; 375/227

(57) ABSTRACT

The present invention is directed to a method and system for detecting and compensating for signal impairments in modulated signals. Phase noise and gain noise based signal impairments can be detected as a function of the difference between the optimal position in the constellation grid (the center) and the actual position in the constellation grid of a received symbol. As symbols are received, they are compared to optimal positions and a measure of the phase noise and gain noise can be determined for each symbol. Over a period of time, the detector can compute an average measure of phase noise and gain noise. When the average measure of phase noise and/or gain noise reaches a predefined threshold, the detector can indicate a phase noise based and/or gain noise based signal impairment has been detected to the receiver. The receiver can adjust one or more receive parameters in order to improve reception. Burst noise based signal impairments can be detected as a function of the number of QAM symbols that have an i component or a q component that exceeds the maximum constellation value in a predefined period of time or in the course of a predefined number of symbols received. When the number of number of QAM symbols having burst noise exceeds reaches a predefined threshold, the detector can indicate a burst noise signal impairment to the receiver and the receiver can adjust one or more receive parameters in order to improve reception.

### CROSS-REFERENCE TO RELATED APPLICATIONS

This application claims any and all benefits as provided by law of U.S. Provisional Application No. 60/867,687 filed Nov. 29, 2006 and U.S. Provisional Application No. 60/884,874 filed Jan. 13, 2007, which are hereby incorporated by reference in their entirety.

### STATEMENT REGARDING FEDERALLY SPONSORED RESEARCH

Not Applicable

### REFERENCE TO MICROFICHE APPENDIX

Not Applicable

### BACKGROUND

The present invention is directed to methods and systems for detecting and correcting QAM signal impairments.

Digital data communication systems generally transmit symbols from a finite alphabet, A, at discrete, (usually periodic) time instants known as baud instances. These symbols can be used to modulate a Radio Frequency (RF) carrier's amplitude and phase for transmission over a variety of media (e.g. terrestrial, underwater, cable, etc.) to a remote receiver or user. There exist various modulation formats, such as Quadrature Amplitude Modulation (QAM), vestigial sideband modulation (VSB) and orthogonal frequency division multiplexing (OFDM) etc. which may be tailored to the application or transmission medium.

QAM has been adopted by the Society of Cable Television Engineers (SCTE) for broadcast in the US and by the Digital Audio Visual Council (DAVIC) and the Multimedia Cable Network System (MCNS) standardization bodies for the transmission of digital TV signals over Coaxial, Hybrid Fiber Coaxial (HFC), and Microwave Multi-port Distribution Wireless Systems (MMDS) TV networks.

To provide reliable data estimates from a QAM modulated signal, a receiver desirably performs a number of functions, including (but not limited to) RF demodulation, synchronization of a carrier loop to the RF carrier, synchronization of the clock signal to the baud sampling instants, equalization, and decoding. Because the transmitted signal is subject to a propagation medium which has a frequency response characteristic and may introduce distortion, an equalizer is used to compensate for the frequency response characteristic of the transmission channel and to mitigate the distortion caused by the transmission channel.

Generally, in the transmission of modulated signals such as those used by DTV and cable boxes, signal impairments such as Phase Noise, gain noise (such as AM Hum), Additive White Gaussian Noise (AWGN) and Burst Noise are encountered. These signal impairments, if not corrected will stress the carrier recovery and equalization components of the system and can result in uncorrectable symbol errors. Phase Noise is generated by the oscillator frequency jitter in the modulator and the demodulator. The sidebands of the Phase Noise signal are coherent, which means that the upper frequency sidebands have a definite phase relationship to the lower frequency sidebands. Gain noise is noise caused by power fluctuations which results in periodic amplitude fluctuation of the received signal, such as AM hum. AWGN, generated as a result of the thermal vibrations of atoms has a flat or near flat frequency spectrum. Burst Noise, originated due to the undesired electromagnetic interferences that results from the switching of household equipment, is intermittent and occurs infrequently.

In order to compensate for Phase Noise, the carrier loop bandwidth has to be increased whereas to compensate for AWGN and Burst Noise, the carrier loop bandwidth should be decreased. Thus, the correction for one impairment sometimes increases the susceptibility for the other impairment.

In the prior art, several attempts have been made to compensate for or to eliminate noise resulting from signal impairments. U.S. Pat. No. 5,315,618 to Yoshida discloses a method and apparatus for canceling periodic carrier phase jitter. In the Yoshida invention, if a demodulated complex baseband signal is deviated in phase from a QAM signal alphabet due to phase jitter, the phase error is detected, and a replica of the phase jitter is calculated and applied to impart phase rotation for canceling out the phase jitter that is contained in the complex baseband signal. U.S. Pat. No. 4,675,613 to Naegeli et al. discloses a circuit in a synchronous detector system that is provided to minimize and compensate for the errors induced by phase modulation and gain noise in the system. In one embodiment, a first-order correction of such errors is achieved by equipping the synchronous detector system with a phase lock loop having a constant loop filter noise bandwidth to reduce the phase noise and an RMS detector for first order correction of the gain noise. The resolution filter passing the signal to the RMS detector is made to have a noise bandwidth identical to the loop noise bandwidth. U.S. Pat. Nos. RE 31,351 and 4,213,095 to Falconer disclose, respectively, a feedback nonlinear equalization of modulated data signals and a feed-forward nonlinear equalization of modulated data signals. In the '351 patent, a receiver for a QAM signal impaired by linear and non-linear distortion, phase jitter and additive noise includes circuitry which compensates for these impairments. In particular, the receiver includes a processor which subtracts a feedback nonlinear signal from each sample of the received signal, either prior to or subsequent to demodulation, providing compensation for non-linear inter-symbol interference. In the '095 patent, a feed-forward non-linear signal is added to each sample of a linearly equalized received signal to provide compensation for nonlinear inter-symbol interference. In each of the patents, the feedback/feed-forward nonlinear signal is comprises of a weighted sum of products of individual ones of the samples and their complex conjugates.

U.S. Pat. No. 6,249,180 to Maalej, et al. discloses a QAM demodulator having a carrier recovery circuit that includes a phase estimation circuit and an additive noise estimation circuit which produces an estimation of the residual phase noise and additive noise viewed by the QAM demodulator. The '180 patent computes phase noise as the cross correlation of Di and Dq, where Di and Dq are the distance between the slicer output S(n), and equalized symbol Z(n) in the I and Q axes, respectively. A QAM base band symbol consists of an I component and a Q component, Z(n)=Z_{I}(n)+j*Z_{Q}(n)). So phase noise, ph(n)=E{Di*Dq}. However, this cross correlation does not accurately represent the geometric phase variation of the constellation.

### SUMMARY

The present invention is directed to a method and system for detecting and correcting impairments in modulated signals, such as QAM, VSB and OFDM signals. The impairment detector takes inputs from the receiver and using, for example, the geometric properties of the constellation, determines a measure of phase noise, a measure of gain noise and a measure of burst noise. These measures can be used to provide an indication of the phase variation due to phase noise, gain variation due to gain noise, and random burst errors due to burst noise. The detected signal impairments can be corrected by adjusting one or more parameters of one or more components of the receiver to compensate for the detected signal impairments in order to improve reception of the signal.

The phase noise and gain noise measures can be calculated for each constellation grid location in the constellation, e.g. for QAM64 there are 64 constellation grid locations, one for each of the symbols in the constellation. In accordance with an embodiment of the invention, the constellation grid can be partitioned into an inner constellation and an outer constellation and four basic noise measurements can be determined: inner constellation phase noise measure, inner constellation gain noise measure, outer constellation phase noise measure, and outer constellation gain noise measure. These measures can be used to detect and provide an indication of signal impairments due to phase noise and gain noise.

In accordance with an embodiment of the invention, QAM signal impairments can be detected as a function of a running average of the phase noise measures and the gain noise measures of one or more pairs of symbol locations, one (or more) from the inner constellation and one (or more) from the outer constellation. When a noise impairment is detected, one or more of the signal processing parameters of the receiver can be adjusted to compensate for the QAM signal impairment detected. Further, the signal processing parameters of the receiver can be adjusted as a function of the signal noise impairment detected in order to improve reception.

In accordance with an embodiment of the invention, burst noise can be detected as a function of the symbols that exceed the maximum symbol value of the constellation (and fall outside the outer boundary of the constellation) and the frequency of the symbols exceeding the maximum symbol value are received. For each symbol that includes an in-phase component or quadrature-phase component that exceeds the maximum symbol value of the constellation, the magnitude of the component that exceeds the maximum symbol value can be determined and compared to a predefined magnitude threshold. In accordance with an embodiment of the invention, the system can maintain a count of the number of received symbols that exceed the magnitude threshold and where the count exceeds a predefined count threshold, the system can indicate that burst noise has been detected. In addition, the indication that burst noise is detected and/or the count value can be used to tune or adjust the receiver in order to improve data reception.

The present invention provides both a measure of phase noise and a measure of gain noise, which geometrically represent the variation in phase and gain by projecting the variation onto the phase and gain coordinate system. In one embodiment of the invention, the QAM constellation is partitioned into a set of inner measures and a set of outer measures. This provides extra information in order to identify phase noise and gain noise. The invention also provides method for determining burst noise as a function of the burst noise magnitude and frequency.

In accordance with implementations of the invention, one or more of the following capabilities may be provided. The present invention provides an improved method and system for detecting phase noise, gain noise and burst noise in QAM signals by receivers (such as Digital Televisions, set top boxes and cable modems). Further, the improved method and system for detecting phase noise, gain noise and burst noise in QAM signals by receivers can also be used to adjust or tune the receiver in order to improve reception. The receiver can be adjusted according to discrete modes, such as a phase noise compensated mode, gain noise compensated mode or a burst noise compensated mode or the receiver can be adjusted gradually and/or proportionally as a function of the measure of the amount of phase noise, gain noise and burst noise that is detected.

These and other capabilities of the invention, along with the invention itself, will be more fully understood after a review of the following figures, detailed description, and claims.

### BRIEF DESCRIPTION OF THE FIGURES

FIG. 1 is a block diagram of a QAM receiver according to the present invention.

FIG. 2 is a diagram of a constellation of QAM64, illustrating the variation of input symbols locations within the constellation grid.

FIG. 3 is a diagram of a constellation of QAM64 according to the present invention.

FIG. 4 is a diagram of a phase locked loop according to the present invention.

### DETAILED DESCRIPTION OF PREFERRED EMBODIMENTS

The present invention is directed to a method and system for detecting and correcting signal impairments in modulated signals. Phase noise and gain noise based signal impairments can be detected as a function of the difference between the ideal position in the constellation grid (the center) and the actual position in the constellation grid of a QAM symbol. As symbols are received, they are compared to the ideal positions and a difference vector is determined for each symbol. Over a period of time, the system can compute an average difference vector. When the average difference vector reaches a predefined threshold, the system can indicate that a signal impairment has been detected. The system can adjust, directly or indirectly, one or more receiver parameters as a function of the signal impairment detected or the average difference vector to correct for signal impairments detected.

Burst noise signal impairments can be detected by counting the number occurrences in a given time period that the magnitude of a symbol exceeds the maximum limit value for the outermost constellation locations in the grid. The system can keep a count of how many received symbols exceeded the maximum limit value for the outermost constellation location and where the number of the count exceeds a predefined threshold before a timer expires (or within a predefined time period), the system can indicate to the receiver that burst noise is detected. Alternatively, the system can determine the magnitude of the distance by which a received symbol exceeds the maximum limit for outermost constellation locations in order to count how many symbols had a magnitude that exceeded the maximum limit value for the outermost constellation location by a predefined burst magnitude threshold, where the number of the count exceeds a predefined threshold before a timer expires (or within a predefined time period), the system can indicate to the receiver that burst noise is detected. The system can adjust one or more receiver parameters as a function of the signal impairment detected or the count or a running average of the count to correct for the detected signal impairments.

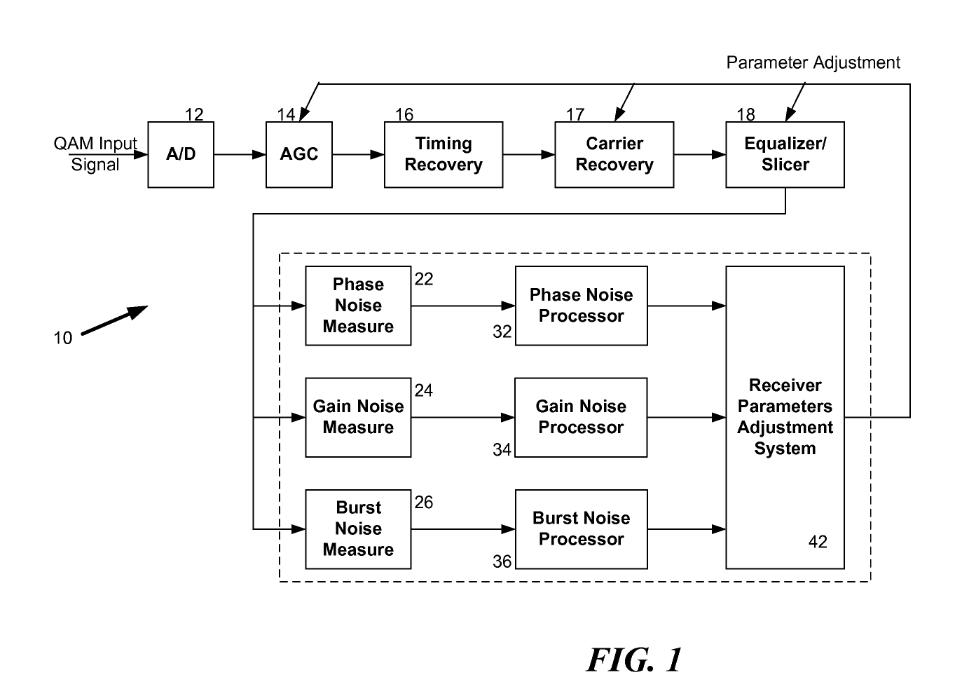

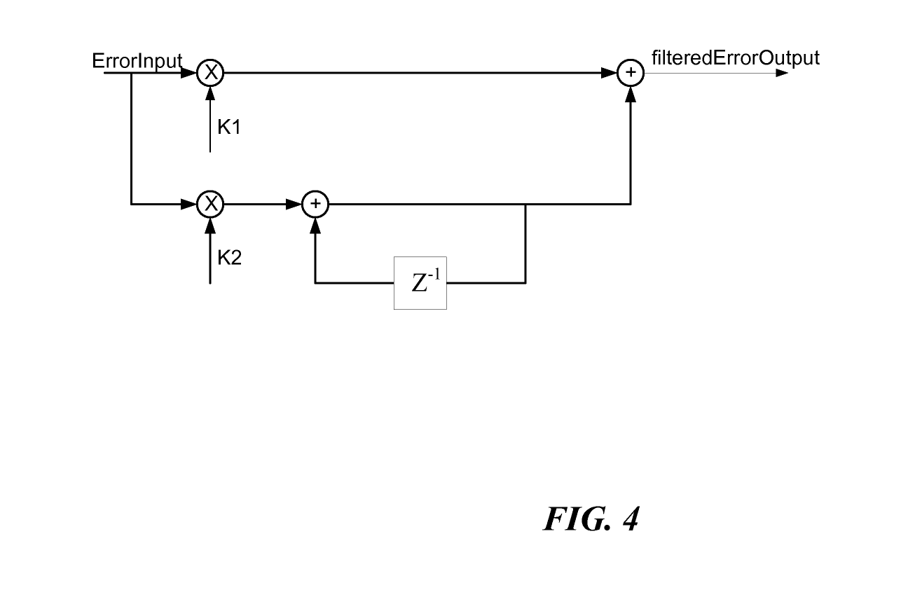

FIG. 1 shows a diagram of a QAM receiver 10 in accordance with an embodiment of the invention. The QAM receiver can include an analog-to-digital converter (“A/D”) 12, an Automatic Gain Control circuit (“AGC”) 14, a timing recovery circuit 16, a carrier recovery circuit 17 and an equalizer and slicer circuit 18. The equalizer and slicer circuit 18 can, optionally, also be broken into two separate circuits. The QAM receiver can receive a QAM analog input signal which is converted to a digital signal via an analog-to-digital converter 12. The receiver 10 can also include other circuits as may be necessary to process the incoming QAM signal. The AGC circuit 14, the carrier recovery circuit 16 and the equalizer and slicer circuit 18 can be capable of being adjusted in order to tune the receiver for various signal impairments. The AGC 14 and the carrier recovery circuit 17 can include a phase locked loop (PLL) having an adjustable bandwidth as shown in FIG. 4. This can be accomplished by changing the electrical characteristics of the circuit or by changing one or more parameter values that result in a change in the electrical characteristics of the circuit.

In accordance with an embodiment of the invention, the output of the equalizer and slicer 18 is input into the phase noise measure block 22, the gain noise measure block 24 and the burst noise measure block 26. The phase noise measure block 22 generates a measure of the phase noise detected and inputs this information into a phase noise processor 32. The gain noise measure block 24 generates a measure of the gain noise detected and inputs this information into a gain noise processor 34. The burst noise measure block 24 generates a measure of the burst noise detected and inputs this information into a burst noise processor 36.

The phase noise measure block 22 can generate a measure of phase noise detected that can include, for each symbol processed, information relating to the deviation of the symbol value from the optimal expected value if there were no noise. This measure can be determined as the difference between the optimal symbol value (the value without noise in the center of the constellation location) and the actual value of the received symbol. In other embodiments, the measure can be determined using the variance or standard deviation between the optimal symbol value and the actual symbol value. In addition, the phase noise measure block 22 can generate a running average of phase noise (the symbol deviation) for each symbol location monitored. In alternative embodiments, the phase noise measure block 22 can generate other measurement values which are a function of the deviation of the symbol value from the optimal expected symbol value, for example, a mean of phase noise (symbol deviation), a mean of phase noise (symbol deviation) over time or over a range or sequence of received symbols. The phase noise measure block 22 can be implemented as a circuit, using programmable logic, or in firmware or software for a microprocessor.

The gain noise measure block 24 can generate a measure of gain noise or AM hum detected that can include, for each symbol processed, information relating to the deviation of the symbol value from the optimal expected value if there were no noise. This measure can be determined as the difference between the optimal symbol value (the value without noise in the center of the constellation location) and the actual value of the received symbol. In other embodiments, the measure can be determined using the variance or standard deviation between the optimal symbol value and the actual symbol value. In addition, the gain noise measure block 24 can generate a running average of gain noise (the symbol deviation) for each symbol location monitored. In alternative embodiments, the gain noise measure block 24 can generate other measurement values which are a function of the deviation of the symbol value from the optimal expected symbol value, for example, a mean of gain noise (symbol deviation), a mean of gain noise (symbol deviation) over time or over a range or sequence of received symbols. The gain noise measure block 24 can be implemented as a circuit, using programmable logic, or in firmware or software for a microprocessor.

The burst noise measure block 26 can generate a measure of burst noise detected that can include, for each symbol processed, information relating to the deviation of the symbol value from the maximum symbol value (outside the outer boundary of the constellation) if there were no burst noise. This measure can be determined as the difference between the maximum symbol value (the value of the outer boundary of the constellation) and the actual value of the received symbol. In other embodiments, the measure can be determined using the variance or standard deviation between the maximum symbol value and the actual symbol value. In addition, the burst noise measure block 26 can generate a running average of burst noise (the amount of symbol deviation) for each symbol location monitored. In alternative embodiments, the burst noise measure block 26 can generate other measurement values which are a function of the deviation of the symbol value from the optimal expected symbol value, for example, a mean of burst noise (symbol deviation), a mean of burst noise (symbol deviation) over time or over a range or sequence of received symbols. The burst noise measure block 26 can also maintain a counter that counts the number of symbols that fall outside the outer boundary of the constellation or that exceed the outer boundary of the constellation by a predefined threshold amount. The counter value can be saved and the counter can be restarted after a predefined time period (such as at the expiration of a timer) or after the total number of symbols received reaches a predefined value. The saved counter value can be forwarded for further processing. The phase noise measure block 22 can be implemented as a circuit, using programmable logic, or in firmware or software for a microprocessor.

The Phase Noise processor 32 receives the measure of the phase noise or the average of the measure of phase noise and determines whether this measure exceeds the threshold for indicating that phase noise is detected. If the phase noise or the average phase noise measure exceeds a pre-determined or programmable threshold for indicating that phase noise is detected, the Phase Noise processor 32 communicates an indication that phase noise is detected to the Receiver Parameter Adjustment system 42. The Phase Noise processor 32 can also send a measure of the phase noise detected or the average of the measure of phase noise to the Receiver Parameter Adjustment system 42 and the Receiver Parameter Adjustment system 42 can use this measure to determine how to adjust the receiver or receiver parameters.

The gain noise processor 34 receives the measure of the gain noise or the average of the measure of gain noise and determines whether this measure exceeds the threshold for indicating that gain noise is detected. If the gain noise or the average gain noise measure exceeds a pre-determined or programmable threshold for indicating that gain noise is detected, the gain noise processor 34 communicates an indication that gain noise is detected to the Receiver Parameter Adjustment system 42. The gain noise processor 34 can also send a measure of the gain noise detected or the average of the measure of gain noise to the Receiver Parameter Adjustment system 42 and the Receiver Parameter Adjustment system 42 can use this measure to determine how to adjust the receiver or receiver parameters.

The Burst Noise processor 36 receives the measure of the burst noise and/or the burst noise count and determines whether either the measure of burst noise or the burst noise count (or both) exceed(s) the threshold for indicating that burst noise is detected. If the measure of burst noise or the burst noise count (or both) exceed(s) their respective pre-determined or programmable thresholds for indicating that burst noise is detected, the Burst Noise processor 36 communicates an indication that burst noise is detected to the Receiver Parameter Adjustment system 42. The Burst Noise processor 34 can also send a measure of the burst noise detected or the burst noise count to the Receiver Parameter Adjustment system 42 and the Receiver Parameter Adjustment system 42 can use the measure of the burst noise detected or the burst noise count to determine how to adjust the receiver or receiver parameters.

In an alternative embodiment, the functionality of the phase noise measure block 22, gain noise measure block 24, the phase noise processor 32 and the gain noise processor 34 can be combined into a single phase and gain noise processing system that receives the output of the equalizer and slicer 18, determines the measures of phase and gain noise, determines whether phase and/or gain noise is detected and can provide an appropriate indication to the receiver to adjust the receiver directly or to a receiver parameter adjustment system to formulate and send the appropriate signals to adjust the receiver to compensate for the noise impairment detected. The functionality of the burst noise measure block 26 and the burst noise processor 36 can be combined into a single burst noise processing system that receives the output of the equalizer and slicer 18, determines a measure of burst noise, determines whether burst noise is detected and can provide an indication to the receiver to adjust the receiver directly or to a receiver parameter adjustment system to formulate and send the appropriate signals to adjust the receiver to compensate for the noise impairment detected. As one of ordinary skill would appreciate, each of the phase noise measure block 22, the gain noise measure block 24, the burst noise measure block 24, the phase noise processor 32, the gain noise processor 34, the burst noise processor 36 and the receive parameter adjustment system 42 and the associated functionality can be implemented as an electronic circuit, a programmable gate array, a combination of hardware and software or entirely in software. Further, the functionality of the above identified elements can be combined in any number of combinations, including all of the functionality embodied in a single component as indicated by the dashed line in FIG. 1.

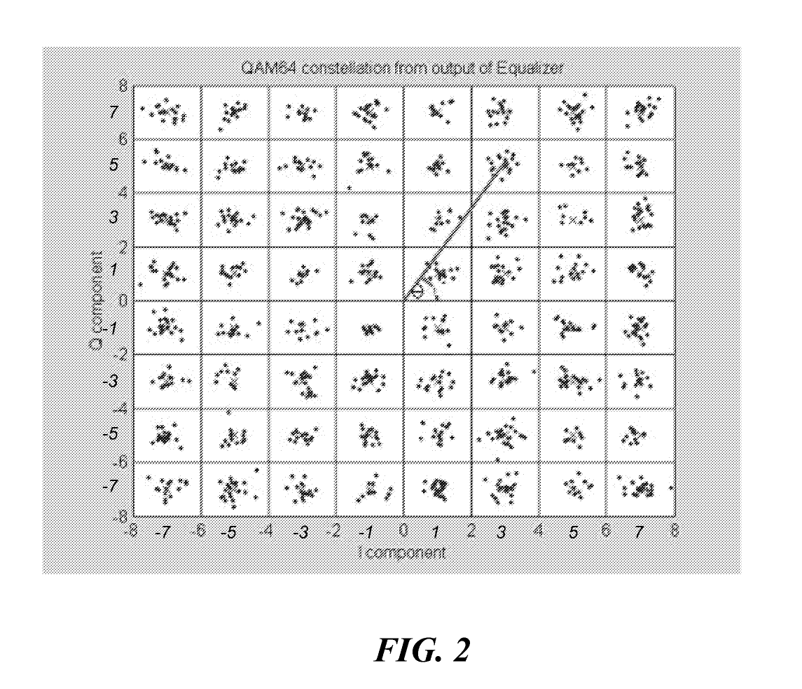

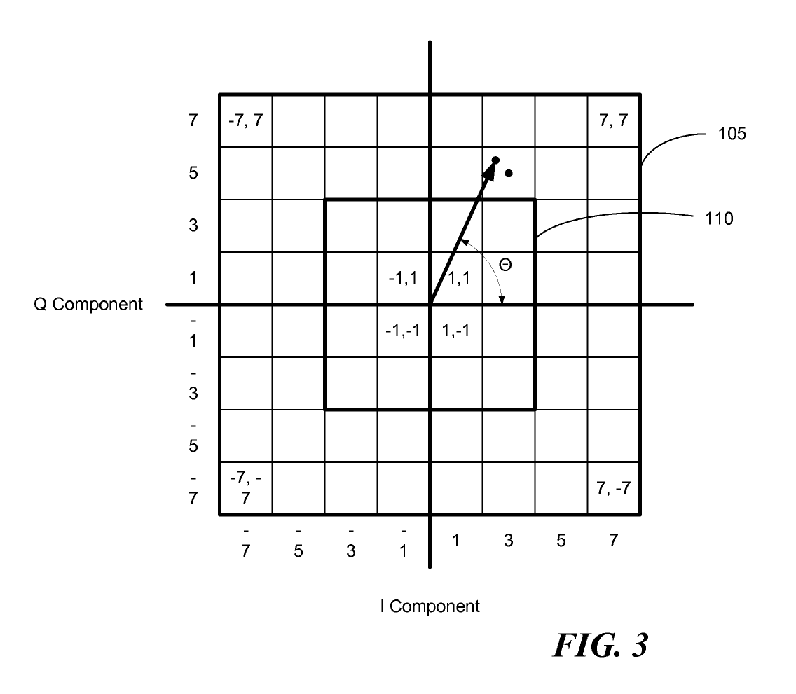

FIGS. 2 and 3 show an example of a QAM64 constellation that could be the output of the equalizer and slicer 18. The QAM64 constellation can be represented in the form of an eight by eight grid, each grid location being associated with a constellation symbol that can be mapped to an associated numeric value. For each symbol received, the receiver determines which of the 64 grid locations is the best match and then performs a table lookup or other translation process to determine the numeric value associated with the received symbol. Each symbol includes an I component (or in-phase component) and a Q component (or quadrature-phase component) and the values of the I component and the Q component are used to determine the symbol based on its location in the constellation. The constellation grid shown in FIG. 2 uses odd numbers to identify grid locations and even numbers to identify symbol thresholds. For example as shown in FIG. 2, if the I component is between 2 and 4 and the Q component is between 4 and 6, symbol would fall in the grid location 3, 5. The symbol can also be represented as a vector having a magnitude (the square root of the sum of I² and Q²) and a phase angle, θ. FIG. 3 shows an example of how the constellation can be partitioned into an inner constellation and an outer constellation. Line 110 indicates the boundary between the inner constellation (|I| and |Q| is 1 or 3) and the outer constellation (|I| and |Q| is 5 or 7). Boundary line 110 can be adjusted according to the desired performance of the receiver. Line 105 indicates outer boundary of the constellation and the maximum symbol value for the constellation.

Due to noise, the symbol values do not always fall in the center of the designated grid location. For example, as illustrated in FIG. 2, the symbol in grid location 3, 5 can have an I component value of 3.2 and Q component value of 5.5 and the symbol error is represented by Di which equals 0.2 and Dq which equals 0.5. Similarly, the symbol 3.2, 5.5 can be represented as a vector having a magnitude and a phase angle which has a magnitude error represented by Dm which equals approximately 0.5322 and a phase angle error represented by Dθ which equals approximately 0.7722 degrees. In accordance with an embodiment of the invention, the difference between the received symbol values and the ideal symbol value (the center of a grid location, e.g. 3, 5) can be used to determine a measure of phase noise and/or gain noise.

In some circumstances, the symbol values exceed the maximum value of the constellation. For example in FIGS. 2 and 3, symbols with an I or Q component value greater than 8 or less than −8 exceed the maximum value of the constellation, boundary line 105. In accordance with an embodiment of the invention, symbols having an I or Q component value that exceeds the maximum value of the constellation can be used to determine an indication of burst noise. The difference between the maximum value of the constellation and the component value of the symbol can be used to determine a measure of burst noise. For example, if the I component value of a received symbol was 8.7, the measure of burst noise for the in-phase component can be indicated as 0.7.

In accordance with an embodiment of the invention, phase noise and/or gain noise can be detected by evaluating one or more of the received symbols that fall in one or more constellation grid locations. As a person having ordinary skill would appreciate, it may be desirable to evaluate all or almost all the symbols received by the receiver. However, this would require significant computational resources and depending on the number of symbols in the constellation, may not be economical. Further, where speed and efficiency are desired, a few symbols corresponding to one or two constellation grid locations can be used to determine phase noise and/or gain noise. Preferably, each and every received symbol corresponding to one or more constellation grid locations can be used to detect phase noise and/or gain noise. Alternatively, less than each and every received symbol corresponding to one or more constellation grid locations can be used to detect phase noise and/or gain noise. As one of ordinary skill would appreciate, the percentage of the symbols to be evaluated (relative to the number of symbols received) can be selected to achieve the desired cost/performance characteristics.

For each grid location in the constellation diagram in FIGS. 2 and 3, the measure of phase noise (I,Q), and gain noise(I,Q) are calculated, where I is the in-phase component, and Q is the quadrature-phase component of the QAM symbol. Each grid location represents one valid QAM64 symbol, where the perfect symbol (e.g. resulting from an unimpaired signal) is located at the center of the box and for each symbol, a value for the in-phase component and the quadrature-phase component are predefined. (I,Q) in capital letter refers to the center of the box, where (i,q) in lower case letter refers to received and equalized symbols with some residual impairments that results in symbol scatter around center point in that box as shown in FIG. 2. In accordance with an embodiment of the invention, the measure of phase noise (PhaseNoiseMeasure) and gain noise (GainNoiseMeasure) can be determined by the equation:

$$[ \begin{matrix}PhaseNoiseMeasure ( i , q ) \\ GainNoiseMeasure ( i , q )\end{matrix} ] = [ \begin{matrix}cos θ & - sin θ \\ sin θ & cos θ\end{matrix} ] \times [ \begin{matrix}Di \\ Dq\end{matrix} ] \qquad ( 1 )$$

where Di, and Dq are the distance between the received QAM symbol (equalizer output) and the center point of the symbol location (I,Q) along the I axis and Q axis respectively, i.e. Di=i−I, and Dq=q−Q. The angle θ is the angle between the vector to the center point of the symbol location (I,Q) in the constellation and the I axis as shown in FIGS. 2 and 3.

In accordance with one embodiment of the invention, the method for computing the average phase noise and gain noise measure for each grid location can include the following elements:
1. Receive new symbol from the equalizer;
2. Determine which grid location in the constellation diagram it belongs to, and assign it to that grid location;
3. For example, if the symbol belongs to box/bin (3,5), then we determine the phase noise measure [PhaseNoiseMeasure(3,5)] and the gain noise measure [GainNoiseMeasure(3,5)], using Eq (1) above.
4. Calculate the time based average for phase noise measure [E{PhaseNoiseMeasure(3,5)}] and for gain noise measure [E{GainNoiseMeasure (3,5)}];
5. Repeat 1-4 for the next symbol

Over time this will produce a running average for phase noise measure E {PhaseNoiseMeasure(i,q)} and a running average for gain noise measure E {GainNoiseMeasure(i,q)} for all the I,Q values that constitutes valid perfect symbols in the QAM constellation. For example, for QAM64 I belongs to {−7,−5,−3,−1,1,3,5,7}, and Q belongs to {−7,−5,−3,−1,1,3,5,7}.

In accordance with an embodiment of the invention, the detection of phase and/or gain noise can be achieved more efficiently by partitioning the constellation into an inner set of grid locations and an outer set of grid locations. In one embodiment, with reference to FIGS. 2 and 3, the inner set of grid locations can be (1,1), (−1,1), (−1,−1), (1,−1) and the outer set of grid locations can be (7,7), (−7,7), (−7,−7), (7,−7). In this embodiment, the total number of grid locations can be less than or equal to the total number of grid locations in the constellation.

In an alternative embodiment, the inner set of grid locations consists of only one location (1,1) and the outer set of grid locations consists of only one location (7,7). As one of ordinary skill would appreciate, any two grid locations along the line I=Q or −I=Q can be used. As one of ordinary skill would appreciate, the selection of these or similar locations simplifies the calculation and computing resources (or hardware) needed to implement the phase noise and gain noise detector components. Because θ is 45 degrees, and therefore sin θ=cos θ, Eq. (1) above can be reduced to addition and subtraction with scaling. Alternatively, the scaling can be omitted as all the values are scaled by the same value: sin θ=cos θ=\sqrt{0.5}.

In accordance with an embodiment of the invention, a running or time based average of the measure of phase noise [E{PhaseNoiseMeasure(i,q)}] and the measure of gain noise [E{GainNoiseMeasure(i,q)}] can be determined for each received symbol that corresponds to one of grid locations in the inner set of grid locations or the outer set of grid locations. In one embodiment, one grid location (for example 1,1) can be selected to represent the inner set and one grid location (for example, 7,7) can be selected to represent the outer set. This would result in at least four values:
E{PhaseNoiseMeasure(I_{Inner},Q_{Inner})} and E{PhaseNoiseMeasure(I_{Outer},Q_{Outer})}, and
E{GainNoiseMeasure(I_{Inner},Q_{Inner})} and E{GainNoiseMeasure(I_{Outer},Q_{Outer})}, or in the example, E{PhaseNoiseMeasure(1,1)} and E{PhaseNoiseMeasure(7,7)}, and
E{GainNoiseMeasure(1,1)} and E{GainNoiseMeasure(7,7)}.

In accordance with one embodiment of the invention, the determination of whether phase noise has been detected can be based on a set of difference signals and a set of thresholds related to the impairment measured at the outer set of constellation location(s) and the difference signals which can include measures from the inner and outer constellations.

In one embodiment, four signals (tn), including three difference signals (t1, t2, t3) can be calculated, and compared with one or more thresholds, in order to detect phase noise.

t1=E{PhaseNoiseMeasure(I_{Outer},Q_{Outer})}−E{PhaseNoiseMeasure(I_{Inner},Q_{Inner)};}

t2=E{PhaseNoiseMeasure(I_{Outer},Q_{Outer})}−E{GainNoiseMeasure(I_{Inner},Q_{Inner})};

t3=E{PhaseNoiseMeasure(I_{Outer},Q_{Outer})}−E{GainNoiseMeasure(I_{Outer},Q_{Outer})};

t4=E{PhaseNoiseMeasure(I_{Outer},Q_{Outer})};
If ( (t1>th1) && (t2>th1) && (t3>th1) && (t4>th2))
Then PhaseNoiseState=DETECTED;

Where th1 and th2 are threshold values that can depend on the receiver design and the level of the QAM signal received. The threshold th1 can be the threshold for evaluating the difference signals (t1,t2 and t3) and for setting the point at which the change in the measure of phase noise is indicative of a signal impairment condition. The threshold th2 can be related to an indication of impairment at the outer constellation location(s), e.g. E{PhaseNoise(I_{Outer},Q_{Outer})} for phase noise. In one embodiment, th1 can be chosen to be approximately 1% of the average amplitude of the QAM symbol where

average amplitude of the QAM symbol=average amplitude of the QAM symbol=\sqrt{E{|S|²/2}}=\sqrt{42}, where S={x+jy}, and x,yε {−7,−5,−3,−1,1,3,5,7} for QAM 64,

and

\sqrt{E{|S|²/2}}=\sqrt{170}, where S={x+jy}, and x, y ε {−15,−13,−11,−9,−7,−5,−3,−1,1,3,5,7,9,11,13,15}

for QAM 256, where E{ } represents expected value or averaging operation and th2 can be chosen to be 3% of the average amplitude of QAM symbol (see above))

In one embodiment of the invention, the determination of whether gain noise has been detected can be based on a set of difference signals and a set of thresholds related to impairment measured at the outer constellation location and the difference signals which can include measures from the inner and outer constellations.

In one embodiment, four signals (gn), including three difference signals (g1, g2, g3) can be calculated, and compared with one or more thresholds, in order to detect gain noise.

g1=E{GainNoiseMeasure(I_{Outer},Q_{Outer})}−E{PhaseNoiseMeasure(I_{Outer},Q_{Outer})};

g2=E{GainNoiseMeasure(I_{Outer},Q_{Outer})}−E{PhaseNoiseMeasure(I_{Inner},Q_{Inner})};

g3=E{GainNoiseMeasure(I_{Outer},Q_{Outer})}−E{GainNoiseMeasure(I_{Inner},Q_{Inner})};

g4=E{GainNoiseMeasure(I_{Outer},Q_{Outer})};
If ( (g1>th1) && (g2>th1) && (g3>th1) && (g4>th2))
Then GainNoiseState=DETECTED;

Where th1 and th2 are threshold values that can depend on the receiver design and the level of the QAM signal received. The threshold th1 can be the threshold for evaluating the difference signals (g1, g2, g3) and for setting the point at which the change in the measure of phase noise and gain noise is indicative of a signal impairment condition. The threshold th2 can be related to an indication of impairment at the outer constellation location(s), e.g. E{GainNoise(I_{Outer},Q_{Outer})} for gain noise. In one embodiment, th1 can be chosen to be approximately 0.4% of the average amplitude of the QAM symbol and th2 can be chosen to be 1.6% of the average amplitude of the QAM symbol where

average amplitude of the QAM symbol=\sqrt{E{|S|²/2}}=\sqrt{42}, whereS={x+jy},andx,yε {−7,−5,−3,−1,1,3,5,7} for QAM 64,

and

\sqrt{E{|S|²/2}}=\sqrt{170}, whereS={x+jy},andx,yε {−15,−13,−11,−9,−7,−5,−3,−1,1,3,5,7,9,11,13,15}

for QAM 256, where E{ } represents expected value or averaging operation

In accordance with an embodiment of the invention, burst noise is detected as a function of the number of symbols that fall outside the outer boundary of constellation grid, i.e. exceed the maximum symbol value. In one embodiment, a measure of burst noise can be determined as a function of the difference between the received symbol value and the outermost grid value. For example, in FIGS. 2 and 3, the maximum symbol value is the outer most boundary of the constellation, which is 8. In one embodiment, the system counts the number symbols that fall outside the constellation grid within a predefined time period or with respect to the total number of symbols received. For example, burst noise could be detected if the number of symbols that fall outside the constellation grid exceeds a threshold number within n seconds or s symbols received. In this example, s can be the total number of symbols received, or the total number of symbols received corresponding to a set of constellation grid locations that is a subset of all the grid locations, for example, the outer most set of grid locations.

In one embodiment, burst noise is determined as a function of burst magnitude, where burst magnitude is given by:

BurstMag=Max(abs(abs(i)−8), abs(abs(q)−8)) for QAM64 (2)

Where i and q are the I component and Q component of each symbol received by the receiver. A value of 8 can be used because in QAM64, the maximum value I or Q is 7. If the i or q falls beyond 8, the slicer may not be able to provide an accurate estimate of the correct symbol because noise may have overwhelmed the receiver causing the value to be misinterpreted and fall outside the decision region. Burst noise can cause the equalized symbol to fall outside the boundary of the decision region (for example, i or q>8).

BurstMag=Max(abs(abs(i)−16), abs(abs(q)−16)) for QAM256

Where i and q are the I component and Q component of each symbol received by the receiver. A value of 16 can be used because in QAM256, the maximum value I or Q is 15. If the i or q falls beyond 16, the slicer may not be able to provide an accurate estimate of the correct symbol because noise may have overwhelmed the receiver causing the value to be misinterpreted and fall outside the decision region. Burst noise can cause the equalized symbol to fall outside the boundary of the decision region (for example, i or q>16).

The BurstMag value can be a measure of how much a given symbol falls outside the outer boundary of the constellation grid, i.e. exceeds the maximum symbol value

The system can determine the BurstMag value and how often BurstMag exceeds a threshold for burst noise. In one embodiment, the burst detector can include a timer which expires after a predefined time period or a symbol counter that counts a predefined number of symbols received. In accordance with an embodiment of the invention, the burst noise measure block can evaluate each received symbol and count the number of times that the BurstMag value for the received symbol exceeds a predefined threshold. The threshold can be chosen, for example, to be 40-50% of average symbol amplitude for the modulation scheme. In one embodiment, for QAM, the threshold was selected to be 45% of the average symbol amplitude, where

the average symbol amplitude of the QAM symbol=\sqrt{E{|S|²/2}}=\sqrt{42}, whereS={x+jy}, andx,yε {−7,−5,−3,−1,1,3,5,7} for QAM 64,

and

\sqrt{E{|S|²/2}}=\sqrt{170}, whereS={x+jy}, andx,yε {−15,−13,−11,−9,−7,−5,−3,−1,1,3,5,7,9,11,13,15}

for QAM 256, where E{ } represents expected value or averaging operation

At the expiration of the timer or when the number of symbols received reaches a predefined threshold value or the symbol counter counts down to zero, the value of the counter (the number of symbols wherein their BurstMag value exceeded the threshold) can be compared to a predefined count threshold. If the value of the counter exceeds the count threshold, an indication of burst noise can be provided.

In accordance with an embodiment of the invention, the system can also modify the operating parameters of the receiver in order to improve reception. The operating parameters of the receiver can be modified in response to or as a function of a signal impairment being indicated. Certain signal impairments can be accommodated by adjusting or tuning the receiver operating parameters to improve reception. However, adjusting a receiver to accommodate one type of impairment can make the receiver sub-optimal and more highly susceptible to another type of impairment. For example, in order to compensate for increased phase noise in the received signal, one or more parameters of the carrier recovery circuit 17 can be adjusted to increase the bandwidth of the carrier recovery circuit 17. However, increasing the bandwidth of the carrier recovery circuit 17 can make the receiver more susceptible to burst noise, which can cause the carrier recovery circuit phase lock loop to become unstable. Similarly, in order to compensate for increased gain noise in the received signal, one or more parameters of the automatic gain control (AGC) circuit 14 can be adjusted to increase the bandwidth of the AGC circuit 14. However, increasing the bandwidth of the AGC circuit 14 can make the receiver more susceptible to burst noise, which can cause the AGC circuit phase lock loop to become unstable. Accordingly, the default or normal operating parameters of the receiver represent a compromise in the receiver's ability to accommodate various different signal impairments.

In accordance with an embodiment of the invention, the receiver operating parameters can be adjusted to accommodate various types of signal impairments as a function of the signal impairments that are detected. Because each receiver design can have a unique set of parameters that need to be determined, one way of determining the proper parameters is empirically, applying various signals to the receiver, each having different types of signal impairments and determining an optimum set of operating parameters for all impairments being considered, these being the normal or default operating settings. Alternatively, the proper parameters can be determined based on the design characteristics of the receiver.

In one embodiment, the receiver (or a receiver adjustment system) can be provided with more than one set of receiver operating settings in order to accommodate different types of signal impairments detected. In this embodiment, when a given type of signal impairment is detected, the type of impairment detected can be provided to the receiver (or the receiver adjustment system) and the receiver operating parameters can be changed to use a different set of receiver operating settings as a function of the signal impairment(s) detected, in order to improve reception. For example, if phase noise was detected, the receiver (or a receiver adjustment system) can change the receiver parameters that relate to the bandwidth of the carrier recovery circuit 17 to increase the bandwidth of the carrier recovery circuit 17. It should be noted that where burst noise is also detected, a different set of receiver operating parameters can be used to increase the bandwidth of the carrier recovery circuit 17 to a lesser degree or to use the default receiver operating parameters. Similarly, if gain noise was detected, the receiver (or a receiver adjustment system) can change the receiver parameters that relate to the bandwidth of the AGC circuit 14 to increase the bandwidth of the AGC circuit 14. It should be noted that where burst noise is also detected, a different set of receiver operating parameters can be used to increase the bandwidth of the AGC circuit 14 to a lesser degree or to use the default receiver operating parameters. In accordance with an embodiment of the invention, the different sets of receiver operating parameters can be determined empirically by subjecting the receiver to different types and combinations of signal impairments and determining optimal sets of receiver operating parameters for each type of signal impairment and combination of signal impairments.

In accordance with one embodiment of the invention, the carrier recovery circuit can help to correct the effects of carrier phase and frequency variations at the receiver. The carrier recovery circuit can also help mitigate the affect of phase noise, via phase offset estimation. The carrier recovery circuit can utilize a phase locked loop (“PLL”) circuit to track carrier phase error. The bandwidth of the PLL determines how much of the phase noise the carrier recovery circuit can track. A high bandwidth setting can be effective for accommodating phase noise in the signal, but can become unstable if there is burst noise in the signal. When burst noise is detected, it can be desirable to decrease the bandwidth of the PLL for the period while burst noise is detected. In addition, AWGN can also be mitigated by decreasing the bandwidth of the PLL.

FIG. 4 shows a diagram of a type-2, 2^{nd} order PLL that can be utilized in the carrier recovery circuit 17 and AGC 14. In accordance with an embodiment of the invention, the bandwidth of the PLL can be increased in the carrier recovery circuit 17 to compensate for phase noise and decreased to compensate for burst noise and AWGN and the bandwidth of the PLL in the AGC 14 can be increased to compensate for gain noise and decreased to compensate for burst noise.

In accordance with an embodiment of the invention, the loop gain K1 can be used to adjust the noise bandwidth of the AGC 14 and carrier recovery 17 PLLs. In accordance with one embodiment of the invention, the carrier recovery PLL is a second order, type 2 PLL and the noise bandwidth is given by, where ξ is the damping ratio:

$$\begin{matrix}NoiseBW = \frac{K 1}{4} * ( 1 + \frac{1}{( 4 * {ξ}^{2} )} ) & ( 3 ) \\ ξ \approx \frac{K 1}{2 \sqrt{K 2}} & ( 4 )\end{matrix}$$

Where K1 and K2 are operating parameters used to control the operation of the PLL. By lowering the value of the damping ratio ξ, the bandwidth of the PLL can be increased. However, a low damping ratio ξ value can result in undesired gain peaking. In one embodiment of the invention, the damping ratio ξ in equation (3) can be set to approximately 0.707 and the value of K1 can be adjusted to change the bandwidth of the PLL in order to achieve the desired compensation.

In accordance with one embodiment of the invention, the bandwidth of the carrier recovery PLL can be adjusted by changing K1 and three different values of K1 can be used; (1) K1_burst when burst noise is detected, (2) K1_nominal, the default value for use with a clean signal, and (3) K1_phasenoise when phase noise is detected. In this example, K1_burst<K1_nominal<K1_phasenoise. Corresponding values for K2 (K2_burst, K2_nominal, K2_phasenoise) can be determined empirically so as to maintain the damping ratio ξ at or near the desired value. Alternatively, corresponding values for K2 (K2_burst, K2_nominal, K2_phasenoise) can be selected to change the damping ratio ξ to further adjust the PLL to compensate for a given type of noise detected. A lookup table can be used to hold the appropriate K1 and K2 values for each of the defined noise conditions.

In accordance with an embodiment of the invention, the receiver operating parameter adjustment can occur as a function of the signal impairment detected as follows:
1. Start with K1=K1_nominal and K2=K2_nominal
2. Measure signal impairment and check for phase noise condition.
3. Check for overall signal integrity, e.g. bit error rate or cluster variance (CV). Compare the CV to the threshold, i.e. −30 dB for QAM64 signal. If signal integrity is very good (for example, CV<−30 dB—note that CV is equivalent to the inverse of the SNR, hence the minus sign), go to 5, else go to 4. Alternatively, if K1=K1_phasenoise, go to 5, else go to 4.
   (This may be necessary in case the signal has phase noise, and the receiver is already compensating by using K2_phasenoise. At this point the measure of phase noise may become small, and indicate no phase noise. This could cause the system to reset K2 back to K2_nominal, resulting in a hysteresis and causing the reception performance to get worse.)
4. If phase noise is detected, set K1 to K1_phasenoise and K2 to K2_phasenoise in order to increase the bandwidth of carrier recovery PLL.
5. Check for burst noise detected. Since burst noise is random in nature and usually occurs for only a short period of time, it can be given priority over phase noise. If burst noise is detected, and K1 can be set to K1_burst and K2 can be set to K2_burst (reducing bandwidth of carrier recovery PLL) for as long as the burst noise is detected.
6. Go back to 2.

Where Cluster Variance (CV), mean square error of equalized symbol (output of equalizer, y), and symbol estimate (output of slicer, S) CV=E {(y−S)²}.

In an alternative embodiment, the receiver operating parameters can be modified as a function of the measure of the signal impairment detected. In this embodiment, the receiver (or a receiver adjustment system) can receive one or more measures of signal impairments, such as phase noise, gain noise and burst noise and any of these measures or a change in any of theses measures can be used to derive one or more new receiver operating parameters or adjustments thereto. In one embodiment, thresholds can be applied to the measure of signal impairment detected or a change in any of the measures, such that receiver operating parameters are not modified unless the measures of signal impairments (or the change therein) change significantly enough to reach a predefined threshold.

In accordance with one embodiment of the invention, the receiver operating parameters can be modified in an adaptive fashion with more granularity for the range of values for K1 and K2 and to gradually change one or both of these values as the phase noise changes. In this embodiment, the system does not have to rely on the detection state, and can modify the receiver operation parameters based on the measure of the signal impairments or a change in the measure of the signal impairments. One advantage of this adaptive method is that the receiver operating parameters, for example, K1 and K2 can be maintained at their optimum settings. In accordance with an embodiment of the invention, once K1 and/or K2 reach their optimum settings for phase noise, the measure of phase noise will become small, and will not cause a significant change in the values of K1 or K2, enabling K1 and/or K2 to converge around their optimum values. This can help to prevent hysteresis of system causing it to become unstable and making signal recovery more problematic.

In accordance with one embodiment of the invention, K1 can be determined by the equation (5) below:

K1=K1+bound(x*abs(E{PhaseNoise(I_{Outer},Q_{Outer})}−E{PhaseNoise(I_{Inner},Q_{Inner)})-}y*Burst Mag) (5)

Where x is positive and the scaling factor for the difference in the measure of the phase noise between the inner constellation and the outer constellation, and y is positive and the scaling factor for the BurstMag. K2 can be determined from K1, and the damping ratio ξ as shown in equation (6) and which can be simplified by setting ξ to 0.707 for PLL stability in equation (6).

$$K 2 = \frac{{( K 1 )}^{2}}{( 4 * {ξ}^{2} )} = \frac{{( K 1 )}^{2}}{2} ( when ξ = 0.707 ) \qquad ( 6 )$$

Bound is a function used to limit the value of the adaptive term to a preset value so that K1 does not grow to an excessively large value. According to Equation 5, when the difference signal of E{PhaseNoise(I_{Outer},Q_{Outer})}−E{PhaseNoise(I_{Inner},Q_{Inner})} increases indicating the presence of phase noise, K1 will be proportionally increased by the factor of x. At the same time, when there is a presence of burst noise as indicated by BurstMag, the bandwidth will be reduced proportionally to the magnitude of the burst noise and the scaling factor y. The scaling factor y can be chosen to be greater than x, in order to give more priority to burst noise over phase noise.

In an alternative embodiment, another equation can be used to control the carrier recovery PLL bandwidth, decreasing the PLL bandwidth in the presence of burst noise, and increasing the PLL bandwidth in the presence of phase noise.

$$K 1 = K 1 + \frac{F ( t 1 , t 2 , t 3 , t 4 )}{( z * BurstMag )} \qquad ( 7 )$$

where z is a positive number used for scaling, and F( ) is a linear function, such as a weighted combination of t1,t2,t3,t4 as used to determine the state of PhaseNoiseState above. The value of K2 can be determined using equation (6) above.

The linear function F( ) can be determined empirically because each receiver can operate according to its own design characteristics. When BurstMag is small (i.e. no burst noise is detected) F( ) can be determined to cause the value of K1 to increase from a nominal value (when no phase noise is detected, e.g. K1_nominal) to a value of K1 that increases the carrier recovery PLL bandwidth to improve reception under increased phase noise conditions (e.g. K1_phasenoise). However, the output of F( ) is preferably limited whereby under increased phase noise conditions, when burst noise is detected, the value of K1 is decreased (for example, to a level below the nominal value, e.g. K1_burst) in order to avoid carrier recovery PLL instability that can be caused by burst noise when the carrier recovery PLL bandwidth is increased (such as to compensate for increased phase noise conditions). The linear function F( ) can be selected to cause the value of K1 to approach K1_phasenoise when phase noise is detected and to approach K1_burst when burst noise is detected.

In one embodiment, the carrier recovery nominal noise bandwidth can be 100 KHz and for ξ=0.707 and a sampling rate of 10 MHz, K1_nominal can selected to be 0.0267. To compensate for phase noise, the noise bandwidth can be increased to 1.0 MHz by setting K1 to K1_phasenoise which can be 0.266. To compensate for burst noise, the noise bandwidth can be decreased to 10 KHz by setting K1 to K1_burst which can be 0.0026.

As one of ordinary skill will appreciate, the techniques for adjusting the carrier recovery PLL as a function of the phase noise detected can be applied to other components of the receiver that use a phase locked loop. For example, the automatic gain control (“AGC”) 14 includes a phase locked loop which can be adjusted in order to accommodate gain noise. When gain noise is detected, the bandwidth of the AGC PLL can be increased to accommodate the gain noise in the receiver. Similarly, when burst noise is detected, the bandwidth of the AGC PLL can be decreased as described herein, in order to avoid the PLL becoming unstable.

### Correction for Gain Noise

In accordance with one embodiment of the invention, the bandwidth of the AGC PLL can be adjusted by changing K1 and three different values of K1 can be used; (1) K1_burst when burst noise is detected, (2) K1_nominal, the default value for use with a clean signal, and (3) K1_gainnoise when gain noise is detected. In this example, K1_burst<K1_nominal<K1_gainnoise. Corresponding values for K2 (K2_burst, K2_nominal, K2_gainnoise) can be determined so as to maintain the damping ratio ξ at or near the desired value. Alternatively, corresponding values for K2 (K2_burst, K2_nominal, K2_gainnoise) can be selected to change the damping ratio ξ to further adjust the PLL to compensate for a given type of noise detected. A lookup table can be used to hold the appropriate K1 and K2 values for each of the defined noise conditions.

In accordance with an embodiment of the invention, the receiver operating parameter adjustment can occur as a function of the signal impairment detected as follows:
1. Start with K1=K1_nominal and K2=K2_nominal
2. Measure signal impairment and check for gain noise condition.
3. Check for overall signal integrity, e.g. bit error rate or cluster variance (CV). Compare the CV to the threshold, i.e. −30 dB for QAM64 signal. If signal integrity is very good (for example, CV<−30 dB—note that CV is equivalent to inverse of SNR, hence the minus sign), go to 5, else go to 4. Alternatively, if K1=K1_gainnoise, go to 5, else go to 4.
   (This may be necessary in case the signal has gain noise, and the receiver is already compensating by using K1_gainnoise. At this point the measure of gain noise may become small, and indicate no gain noise. This could cause the system to reset K1 back to K1_nominal, resulting in a hysteresis and causing the reception performance to get worse.)
4. If gain noise is detected, set K1 to K1_gainnoise and K2 to K2_gainnoise in order to increase the bandwidth of the AGC PLL.
5. Check for burst noise detected condition. Since burst noise is random in nature and usually occurs for only a short period of time, it can be given priority over gain noise. If burst noise is detected, and K1 can be set to K1_burst and K2 can be set to K2_burst (reducing bandwidth of carrier recovery PLL) for as long as the burst noise is detected.
6. Go back to 2.

Where Cluster Variance (CV), mean square error of equalized symbol (output of equalizer, y), and symbol estimate (output of slicer, S) CV=E{(y−S)²}.

In accordance with one embodiment of the invention, the receiver operating parameters can be modified in an adaptive fashion with more granularity for the range of values for K1 and K2 and to gradually change one or both of these values as the gain noise changes. In this embodiment, the system does not have to rely on the detection state, and can modify the receiver operation parameters based on measure of the signal impairments or a change in the measure of the signal impairments. One advantage of this adaptive method is that the receiver operating parameters, for example, K1 and K2 can be maintained at their optimum settings. In accordance with an embodiment of the invention, once K1 and/or K2 reach their optimum settings for gain noise, the measure of gain noise will become small, and will not cause a significant change in the values of K1 or K2, enabling K1 and/or K2 to converge around their optimum values. This can help to prevent hysteresis of system causing it to become unstable and making signal recovery more problematic.

In accordance with one embodiment of the invention, K1 can be determined by the equation (8) below:

K1=K1+bound(x*abs(E{GainNoise(I_{Outer},Q_{Outer})}−E{GainNoise(I_{Inner},Q_{Inner})})−y*BurstMag) (8)

Where x is positive and the scaling factor for the difference in the measure of the gain noise between the inner constellation and the outer constellation, and y is positive and the scaling factor for the BurstMag. K2 can be determined using equation (6) above in a similar fashion to the carrier recovery PLL, since both the AGC PLL and the carrier recovery PLL can employ the same structure.

Bound is a function used to limit the value of the adaptive term to a preset value so that K1 does not grow to an excessively large value. According to Equation 8, when the difference signal of E{GainNoise(I_{Outer},Q_{Outer})}−E{GainNoise(I_{Inner},Q_{Inner})} increases indicating the presence of gain noise, K1 will be proportionally increased by the factor of x. At the same time, when there is a presence of burst noise as indicated by BurstMag, the bandwidth will be reduced proportionally to the magnitude of the burst noise and the scaling factor y. The scaling factor y can be chosen to be greater than x, in order to give more priority to burst noise over gain noise.

In an alternative embodiment, another equation can be used to control the carrier recovery PLL bandwidth, decreasing the PLL bandwidth in the presence of burst noise, and increasing the PLL bandwidth in the presence of phase noise.

$$K 1 = K 1 + \frac{F ( g 1 , g 2 , g 3 , g 4 )}{( z * BurstMag )} \qquad ( 9 )$$

where z is a positive number used for scaling, and F( ) is a linear function, such as a weighted combination of g1, g2, g3, and g4 as used to determine the state of GainNoiseState above. The value of K2 can be determined using equation (6) above.

The linear function F( ) can be determined empirically because each receiver can operate according to its own design characteristics. When BurstMag is small (i.e. no burst noise is detected) F( ) can be determined to cause the value of K1 to increase from a nominal value (when no gain noise is detected, e.g. K1_nominal) to a value of K1 that increases the AGC PLL bandwidth to improve reception under increased gain noise conditions (e.g. K1_gainnoise). However, the output of F( ) is preferably limited whereby under increased gain noise conditions, when burst noise is detected, the value of K1 is decreased (for example, to a level below the nominal value, e.g. K1_burst) in order to avoid AGC PLL instability that can be caused by burst noise when the AGC PLL bandwidth is increased (such as to compensate for increased gain noise conditions). The linear function F( ) can be selected to cause the value of K1 to approach K1_gainnoise when gain noise is detected and to approach K1_burst when burst noise is detected.

In one embodiment, the AGC nominal noise bandwidth can be 1 KHz and for ξ=0.707 and a sampling rate of 10 MHz, K1_nominal can selected to be 0.0002. To compensate for gain noise, the noise bandwidth can be increased to 4 KHz by setting K1 to K1_gainnoise which can be 0.0011. To compensate for burst noise, the noise bandwidth can be decreased to 500 Hz by setting K1 to K1_burst which can be 0.0001.

### Equalizer Adjustment

In one embodiment of the invention, the equalizer can include a feed forward equalizer and a decision feed back equalizer in order to combat multipath signal impairments. The feed forward equalizer and the decision feed back equalizer can be tapped delay line filters with adaptable coefficients. The feed forward filter's coefficients can be f₀ to fₙ for length n+1 filter. The decision feedback filter's coefficients can be g₀ to gₙ for a length n+1 filter. These coefficients can be adjusted as symbols are received by the receiver.

$${f}_{n} ( t + 1 ) = {f}_{n} ( t ) - μ \frac{\partial {J}^{2}}{\partial t} \qquad ( 10 )$$

Equation 10 shows a coefficient adaptation algorithm using stochastic gradient algorithm, where n is the coefficient index, and t is the sample time index, J is the cost function, and μ is the step size. For more information, see Adaptive Filter Theory(4th Edition) (Prentice Hall, September 2001) by Simon Haykin.

The feed forward equalizer filter can be used to track gain variation in the signal caused by gain noise impairment. The filter controls gain via the biggest coefficient which is usually the coefficient at the center of the filter. For length n+1 filter, the center coefficient is f_{(n+1)/2} . For feed forward equalizer to be able to track gain noise, the step size of the biggest tap should be large enough to track gain variation of the signal. However, in the presence of burst noise, the step size should not be set too high because the filter can become unstable, and the filter will diverge from the optimal coefficient set point.

In accordance with an embodiment of the invention, the receiver operating parameter adjustment can occur as a function of the signal impairment detected as follows:

For every symbol received from the equalizer,
1. Search for the biggest coefficient in feed forward filter, call it the center tap.
2. Set the step size μ of the center tap to be a compromise between the optimum to accommodate gain noise impairment and the optimum to accommodate burst noise impairment. This can be accomplished by selecting the step size μ from a finite set of step size values or, or providing an equation for determining the step size as a function the measure of the gain noise and burst noise detected.
3. Wait for the next sample, and repeat 1-2.

In accordance with an embodiment of the invention, the gain noise tracking capability of feed forward equalizer can be adjusted by adjusting μ, the step size of the center tap. In one embodiment of the invention, three different values of μ can be used: (1)μ_burst when burst noise is detected, (2)μ_nominal, the default value for use with a clean signal, and (3)μ_gainnoise when gain noise is detected. In this example, μ_burst<μ_nominal<μ_gainnoise. In accordance with an embodiment of the invention, the receiver operating parameter adjustment can occur as a function of the signal impairment detected as follows:
1. Start with μ=μ_nominal
2. Measure signal impairment and check for gain noise condition.
3. Check for overall signal integrity, e.g. bit error rate or cluster variance (CV). Compare the CV to the threshold, i.e. −30 dB for QAM64 signal. If signal integrity is very good (for example, CV<−30 dB—note that CV is equivalent to inverse of SNR, hence the minus sign), go to 5, else go to 4. Alternatively, if μ=μ_gainnoise, go to 5, else go to 4.
   (This may be necessary in case the signal has gain noise, and the receiver is already compensating by using μ_gainnoise. At this point the measure of gain noise may become small, and indicate no gain noise. This could cause the system to reset μ back to μ_nominal, resulting in a hysteresis and causing the reception performance to get worse.)
4. If gain noise is detected, set μ to μ_gainnoise in order to increase the gain tracking capacity of feed forward equalizer.
5. Keep checking for burst noise state. Since burst noise is random in nature and usually occurs for a short period of time, it can be given priority over gain noise if detected, and μ will be set to μ_burst for as long as the burst noise is declared as detected
6. Go back to 2.

Where Cluster Variance (CV), mean square error of equalized symbol (output of equalizer, y), and symbol estimate (output of slicer, S) CV=E{(y−S)²}.

The center tap step size μ can also be adaptively adjusted using the measures of phase noise, gain noise and burst noise. By making sure that μ is proportional to the measure of gain noise, and inversely proportional to the measure of burst noise, the center tap's tracking capabilities will be increased as gain noise is detected, and decreased as burst noise is detected. Equation 11 shows adaptive equation for center tap's step size optimized to gain noise, and burst noise.

$$μ = μ + \frac{F ( g 1 , g 2 , g 3 , g 4 )}{w * burstMag} \qquad ( 11 )$$

where w is a positive number used for scaling, and F( ) is a linear function such as weighted combination of g1,g2,g3,g4 as used to determine the state of GainNoiseState above.

Other embodiments are within the scope and spirit of the invention. For example, due to the nature of software, functions described above can be implemented using software, hardware, firmware, hardwiring, or combinations of any of these. Features implementing functions may also be physically located at various positions, including being distributed such that portions of functions are implemented at different physical locations.

Further, while the description above refers to the invention, the description may include more than one invention.

What is claimed is:

1. A method for detecting at least one signal impairment in a modulated signal that includes symbols, the method comprising:
receiving by a signal receiver a plurality of symbols, each having an in-phase component and a quadrature-phase component;
determining for at least one of the received symbols, a measure of gain noise as function of an in-phase component and a quadrature-phase component of the received symbol; and
determining an indication of gain noise impairment of the modulated signal as a function of the measure of gain noise determined for one or more of the symbols; and
changing an operating characteristic of said signal receiver in response to said indication of gain noise impairment.

2. A method according to claim 1 wherein the measure of gain noise is determined as a function of
a difference (Di) between the in-phase component of the received symbol and a predetermined in-phase value for a corresponding symbol of an unimpaired signal,
a difference (Dq) between the quadrature-phase component of the received symbol and a predetermined quadrature-phase value for the corresponding symbol of an unimpaired signal, and
an angle (θ)corresponding to an angle of the corresponding symbol with respect to the in-phase axis.

3. A method according to claim 2 wherein the measure of gain noise is determined according to the equation:
Di(sin θ)+Dq(cos θ).

4. A method according to claim 1 wherein the symbols correspond to a set of N by N grid locations, wherein N can be a positive or negative value, and the measure of gain noise is determined only as a function of symbols that correspond to a set of inner grid locations and symbols that correspond to a set of outer grid locations.

5. A method according to claim 1 wherein the symbols correspond to a set of N by N grid locations, wherein N can be a positive or negative value, and the measure of gain noise is determined only as a function of symbols that correspond to one predetermined grid location of a set of inner grid locations and symbols that correspond to one predetermined grid location of a set of outer grid locations.

6. A method according to claim 5 wherein the measure of gain noise is determined only as a function of symbols that correspond to grid locations (1, 1) and (N, N), where N is a positive or negative number corresponding to an outer most grid location.

7. The method according to claim 1 wherein the modulated signal is received by the signal receiver, the method further comprising:
determining an adjustment of at least one parameter for at least one component of the signal receiver as a function of the indication of gain noise impairment of the modulated signal.

8. The method according to claim 7 wherein said adjustment includes an adjustment of at least one parameter of an automatic gain control component of the signal receiver.

9. A method according to claim 1 further comprising:
determining for at least one of the symbols, a measure of phase noise as function of the in-phase component and the quadrature-phase component of the symbol;
wherein the indication of gain noise impairment of the modulated signal is determined as a function of the measure of gain noise determined for one or more of the symbols and the measure of phase noise determined for one or more of the symbols.

10. A method according to claim 1 further comprising:
determining for at least one of the symbols, a measure of phase noise as function of the in-phase component and the quadrature-phase component of the symbol;
determining an indication of phase noise impairment of the modulated signal as a function of the measure of phase noise determined for one or more of the symbols; and
changing an operating characteristic of said signal receiver in response to said indication of phase noise impairment.

11. The method according to claim 10 wherein the modulated signal is received by the signal receiver, the method further comprising:
determining an adjustment of at least one parameter for at least one component of the signal receiver as a function of the indication of phase noise impairment of the modulated signal.

12. A method according to claim 10 further comprising:
determining for at least one of the symbols, a measure of burst noise as function of at least one of the in-phase component and the quadrature-phase component of the symbol;
determining an indication of burst noise impairment of the modulated signal as a function of the measure of burst noise determined for one or more of the symbols; and
changing an operating characteristic of said signal receiver in response to said indication of burst noise impairment.

13. A method according to claim 12 wherein the symbols correspond to a set of N by N grid locations, wherein N can be a positive or negative value and the measure of burst noise is determined as a function of a count of the symbols having either an in-phase component greater than a predefined value or a quadrature phase component greater than a predefined value.

14. A system for detecting at least one signal impairment in a modulated signal that includes symbols, the system comprising:
a signal receiver adapted to receive a plurality of symbols, each symbol having an in-phase component and a quadrature-phase component;
a gain noise measurement generator adapted to receive a symbol and determine a measure of gain noise as function of an in-phase component and a quadrature-phase component of the received symbol; and
a gain noise processor adapted to receive the measure of gain noise and determine an indication of gain noise impairment of the modulated signal as a function of the measure of gain noise determined for one or more of the symbols; and
a receiver adjustment system adapted to receive the indication of gain noise impairment and determine a change of an operating characteristic of said signal receiver in response to said indication of gain noise impairment.

15. A system according to claim 14 wherein the gain noise measurement generator determines the measure of phase noise as a function of:
a difference (Di) between the in-phase component of the received symbol and a predetermined in-phase value for a corresponding symbol of an unimpaired signal,
a difference (Dq) between the quadrature-phase component of the received symbol and a predetermined quadrature-phase value for the corresponding symbol of an unimpaired signal, and
an angle (θ) corresponding to an angle of the corresponding symbol with respect to the in-phase axis.

16. A system according to claim 15 wherein the gain noise measurement generator determines the measure of gain noise according to the equation:
Di(sin θ)+Dq(cos θ).

17. A system according to claim 14 wherein the symbols correspond to a set of N by N grid locations, wherein N can be a positive or negative value, and the gain noise measurement generator determines the measure of gain noise as a function of only symbols that correspond to a set of inner grid locations and symbols that correspond to a set of outer grid locations.

18. A system according to claim 14 wherein the symbols correspond to a set of N by N grid locations, wherein N can be a positive or negative value, and the gain noise measurement generator determines the measure of gain noise as a function of only symbols that correspond to one predetermined grid location of a set of inner grid locations and symbols that correspond to one predetermined grid location of a set of outer grid locations.

19. A system according to claim 18 wherein the gain noise measurement generator determines the measure of gain noise as a function of only symbols that correspond to grid locations (1, 1) and (N, N), where N is a positive number corresponding to an outer most grid location.

20. The system according to claim 14 wherein the receiver adjustment system is adapted to determine an adjustment of at least one parameter of at least one component of the signal receiver as a function of the indication of gain noise impairment of the modulated signal.

21. The system according to claim 20 wherein said adjustment includes an adjustment of at least one parameter of an automatic gain control component of the signal receiver.

22. A system according to claim 14 further comprising:
a phase noise measurement generator adapted to determine for at least one of the symbols, a measure of phase noise as function of the in-phase component and the quadrature-phase component of the symbol; and
wherein the gain noise processor is adapted to determine the indication of gain noise impairment of the modulated signal as a function of the measure of gain noise determined for one or more of the symbols and the measure of phase noise determined for one or more of the symbols.

23. A system according to claim 14 further comprising:
a phase noise measurement generator adapted to determine for at least one of the symbols, a measure of phase noise as function of the in-phase component and the quadrature-phase component of the symbol;
a phase noise processor adapted to determine an indication of phase noise impairment of the modulated signal as a function of the measure of phase noise determined for one or more of the symbols; and
the receiver adjustment system being adapted to receive the indication of phase noise impairment and determine a change of an operating characteristic of said signal receiver in response to said indication of phase noise impairment.

24. The system according to claim 23 wherein the receiver adjustment system is adapted to determine an adjustment of at least one parameter of at least one component of the signal receiver as a function of the indication of phase noise impairment of the modulated signal.

25. A system according to claim 23 further comprising:
a burst noise measurement generator adapted to determine for at least one of the symbols, a measure of burst noise as function of at least one of the in-phase component and the quadrature-phase component of the symbol;
a burst noise processor adapted to determine an indication of burst noise impairment of the modulated signal as a function of the measure of burst noise determined for one or more of the symbols; and
the receiver adjustment system being adapted to receive the indication of burst noise impairment and determine a change of an operating characteristic of said signal receiver in response to said indication of burst noise impairment.

26. A system according to claim 25 wherein the symbols correspond to a set of N by N grid locations, wherein N can be a positive or negative value and the burst noise measurement generator is adapted to determine the measure of burst noise as a function of a count of the symbols having either an in-phase component greater than a predefined value or a quadrature phase component greater than a predefined value.
